(19) United States
(12) Patent Application Publication
(10) Pub. No.: US 2024/0284764 A1
(43) Pub. Date: Aug. 22, 2024

(54) DISPLAY PANEL, DISPLAY DEVICE AND METHOD OF MANUFACTURING THE SAME

(71) Applicant: Visionox Technology Inc., Suzhou (CN)

(72) Inventors: Xuejing ZHU, Suzhou (CN); Liusong NI, Suzhou (CN); Yi-Yu LAI, Suzhou (CN); Yiming XIAO, Suzhou (CN); Yuan YAO, Suzhou (CN)

(73) Assignee: Visionox Technology Inc., Suzhou (CN)

(21) Appl. No.: 18/618,152

(22) Filed: Mar. 27, 2024

Related U.S. Application Data
(63) Continuation of application No. PCT/CN2023/073735, filed on Jan. 29, 2023.

(30) Foreign Application Priority Data
Aug. 2, 2022 (CN) 202210922544.8

(51) Int. Cl. H10K 59/80; H10K 59/12; H10K 59/122; H10K 102/00

(52) U.S. Cl. CPC H10K 59/873; H10K 59/1201; H10K 59/122; H10K 2102/351

(57) ABSTRACT

Provided are a display panel, a display device, and a method of manufacturing a display panel. The display panel has a display area and a non-display area located on a periphery of the display area, and includes a substrate; a light-emitting device layer disposed on a side of the substrate and located in the display area; a dam disposed on the same side of the substrate and located in the non-display area; a first blocking portion disposed on a side, away from the substrate, of the dam and including a first portion and a second portion; and a packaging film layer located on a side, away from the substrate, of the light-emitting device layer, at least one film layer extending to a side, away from the display area, of the first blocking portion via outer contours of the dam, the first portion, and the second portion.

### CROSS-REFERENCE OF RELATED APPLICATIONS

The present application is a continuation application of International Application No. PCT/CN2023/073735, filed on Jan. 29, 2023, which claims priority to Chinese Patent Application No. 202210922544.8, filed on Aug. 2, 2022, all of which are hereby incorporated by reference in their entireties.

### TECHNICAL FIELD

The present application relates to the technical field of display devices, in particular to a display panel, a display device, and a method of manufacturing a display panel.

### BACKGROUND

Organic light emitting diode (OLED) displays are a kind of self-luminous display. Compared with liquid crystal displays (LCD), the OLED displays do not require backlight, so the OLED displays are lighter and thinner. In addition, the OLED displays have the advantages of high brightness, low power consumption, wide viewing angle, high response speed, wide temperature range, etc., and therefore are increasingly applied in various high-performance display fields.

However, the OLED displays are susceptible to water and oxygen erosion, leading to a decrease in service life. Thin film packaging technologies are commonly used to block water and oxygen intrusion. Existing thin film packaging technologies are prone to separation or fracture during reliability testing due to stress and other factors, resulting in an increased risk of water vapor intrusion.

### SUMMARY

Embodiments of the present application provide a display panel, a display device, and a method of manufacturing a display panel, which can improve packaging reliability.

In a first aspect, an embodiment of the present application provides a display panel, the display panel has a display area and a non-display area located on a periphery of the display area, and the display panel includes a substrate, a light-emitting device layer, a first blocking portion, a dam, and a packaging film layer; the light-emitting device layer is disposed on a side of the substrate and located in the display area; the dam is disposed on the same side of the substrate as the light-emitting device layer and located in the non-display area, the dam is located on a side of the display area in a first direction, and the first direction is parallel to a plane where the substrate is located; the first blocking portion is disposed on a side, away from the substrate, of the dam, the first blocking portion is located on a side of the display area in the first direction, the first blocking portion includes a first portion and a second portion, the second portion is located on a side, away from the substrate, of the first portion, and the second portion extends at least partially beyond the first portion in the first direction; and

The packaging film layer is located on a side, away from the substrate, of the light-emitting device layer, the packaging film layer comprises at least two film layers, at least one of the at least two film layers extends from the display area to a side, away from the display area, of the first blocking portion via outer contours of the dam, the first portion, and the second portion.

In a second, an embodiment of the present application provides a display device, including the display panel in the foregoing embodiment.

In a third aspect, an embodiment of the present application provides a method of manufacturing a display panel, the display panel has a display area and a non-display area located on a periphery of the display area, and the method includes:
forming a dam on a side of a substrate, where the dam is located in the non-display area and on a side of the display area in a first direction, and the first direction is parallel to a plane where the substrate is located;
disposing a preset film layer on the side of the substrate corresponding to a side, away from the substrate, of the dam and patterning the preset film layer to form a first portion and a second portion, where the first portion and the second portion are in contact with each other, the first portion is located on a side, away from the substrate, of the dam, the second portion is located on a side, away from the substrate, of the first portion, and the second portion extends at least partially beyond the first portion in the first direction;
forming at least part of a structure in a light-emitting device layer on the side of the substrate corresponding to the side, away from the substrate, of the dam; and
forming a packaging film layer on a side, away from the substrate, of the light-emitting device layer, where the packaging film layer comprises at least two film layers, at least one of the at least two film layers extends from the display area to a side, away from the display area, of a first blocking portion via outer contours of the dam, the first portion, and the second portion.

The embodiments of the present application provide a display panel, a display device, and a method of manufacturing a display panel. The first blocking portion is added to the dam in the display panel, so that the extension length of at least one of the at least two film layers in the packaging film layer increases. In addition, since the second portion in the first blocking portion extends at least partially beyond the first portion in the first direction, the film layer needs to extend in a curved manner at the corresponding position of the second portion, which can further increase the extension length. Further, if cracks occur in part of the film layer of the packaging film layer, this design will increase the path that the cracks extend to the display area, which can reduce the risk of extension of the cracks to the display area, thereby improving the reliability of the packaging film layer and meeting the packaging requirements of the display panel.

### DESCRIPTION OF THE DRAWINGS

FIG. 1 is a schematic structure diagram of a display panel provided in an embodiment of the present application;

FIG. 2 is a cross-sectional structure diagram of a display panel provided in an embodiment of the present application at position A-A;

FIG. 3 is a cross-sectional structure diagram of a display panel provided in an embodiment of the present application at position B-B;

FIG. 4 is a cross-sectional structure diagram of another display panel provided in an embodiment of the present application;

FIG. 5 is a schematic diagram of an enlarged structure at area Q in FIG. 2;

FIG. 6 is a cross-sectional structure diagram of another display panel provided in an embodiment of the present application at position A-A;

FIG. 7 is a cross-sectional structure diagram of still another display panel provided in an embodiment of the present application at position A-A;

FIG. 8 is a schematic diagram of an enlarged structure at area P in FIG. 7;

FIG. 9 is a cross-sectional structure diagram of still another display panel provided in an embodiment of the present application at position A-A;

FIG. 10 is a cross-sectional structure diagram of another display panel provided in an embodiment of the present application at position B-B;

FIG. 11 is a schematic structure diagram of a display device provided in an embodiment of the present application;

FIG. 12 is a flowchart of a method of manufacturing a display panel provided in an embodiment of the present application;

FIGS. 13A-13D are schematic diagrams of process structures of a method of manufacturing a display panel provided in an embodiment of the present application;

FIG. 14 is a schematic diagram of a process structure of a method of manufacturing a display panel provided in an embodiment of the present application;

FIG. 15 is a schematic diagram of a process structure of a method of manufacturing a display panel provided in an embodiment of the present application; and

FIG. 16 is a schematic diagram of a process structure of a method of manufacturing a display panel provided in an embodiment of the present application.

### DETAILED DESCRIPTION

Features and exemplary embodiments of various aspects of the present application will be described in detail below. In order to make the objectives, technical solutions, and advantages of the present application clearer, the present application will be further described in detail below with reference to the accompanying drawings and specific embodiments. It should be understood that the specific embodiments described here are only intended to explain the present application, but not to limit the present application. For those skilled in the art, the present application can be implemented without some of these specific details. The following descriptions of the embodiments are merely to provide a better understanding of the present invention by showing examples of the present invention.

Organic light-emitting diodes (OLED) are a kind of current type organic light-emitting devices that emit light through the injection and recombination of charge carriers and can be used as light-emitting elements in display panels. However, when an organic light-emitting diode is exposed to moisture and air, the performance of the organic light-emitting diode deteriorates sharply, which in turn reduces the reliability and service life of a display panel. Therefore, effective packaging means are needed to limit the impact of water and oxygen permeation on organic light-emitting diodes.

A packaging film layer is usually disposed on a light-emitting element, and the packaging film layer covers the light-emitting element to prevent the invasion of water and oxygen. However, due to the poor elasticity of part of a film layer in the packaging film layer, cracks may occur under an external force and other factors. If the cracks extend inward to the position of the light-emitting element, the blocking effect of the packaging film layer on water and oxygen cannot be ensured, which easily leads to poor packaging and other problems.

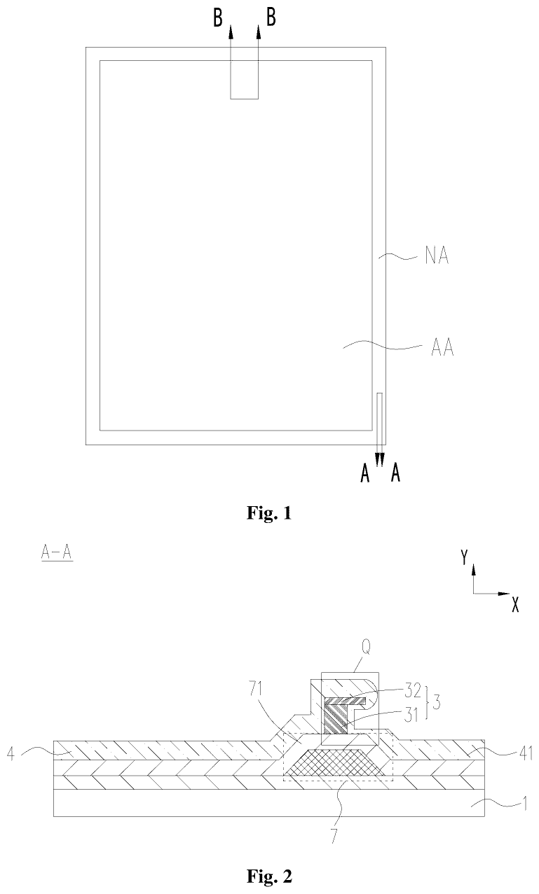

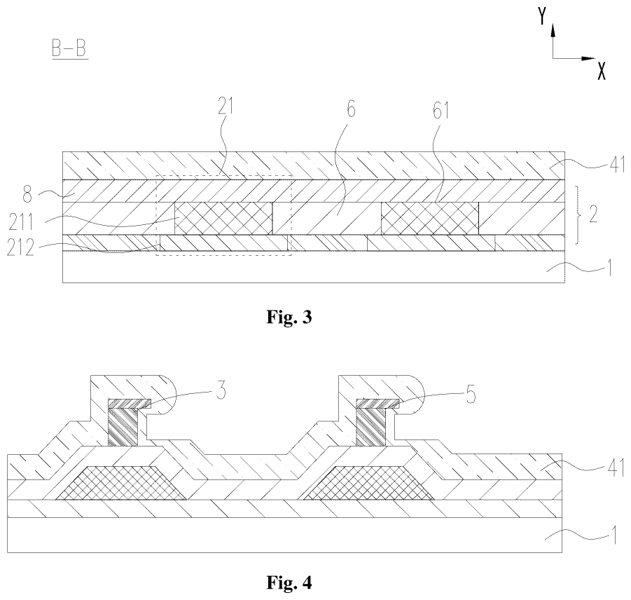

To solve the above problems, an embodiment of the present application provides a display panel. With reference to FIGS. 1 to 3, the display panel has a display area AA and a non-display area NA located on a periphery of the display area AA, and the display panel includes a substrate 1, a light-emitting device layer 2, a first blocking portion 3, a dam 7, and a packaging film layer 4. The light-emitting device layer 2 is disposed on a side of the substrate 1 and located in the display area AA, the dam 7 is disposed on the same side of the substrate 1 and located in the non-display area NA, the dam 7 is located on a side of the display area AA in a first direction X, and the first direction X is parallel to a plane where the substrate 1 is located. Specifically, the dam 7 may alternatively be disposed around the display area AA.

The first blocking portion 3 is disposed on a side, away from the substrate 1, of the dam 7, the first blocking portion 3 includes a first portion 31 and a second portion 32 located on a side, away from the substrate 1, of the first portion 31, and the second portion 32 extends at least partially beyond the first portion 31 in the first direction X.

The packaging film layer 4 is located on a side, away from the substrate 1, of the light-emitting device layer 2, and at least one film layer of the packaging film layer 4 extend to a side, away from the display area AA, of the first blocking portion 3 via outer contours of the dam 7, the first portion 31, and the second portion 32.

The display panel is divided into the display area AA and the non-display area NA, where the display area AA refers to an area having a display function, and the shape and size of the display area AA are not limited by the embodiments of the present application. For example, the display area AA may be of a square or circular structure. The non-display area NA is disposed around the display area AA, the non-display area NA refers to an area that does not have the function of the display area AA, and various signal lines are usually disposed inside the non-display area NA to drive and achieve different functions.

The light-emitting device layer 2 is located on a side of the substrate 1 and includes a plurality of light-emitting units 21 for achieving display effects. For example, the light-emitting device layer 2 includes red light-emitting units for emitting red light, green light-emitting units for emitting green light, and blue light-emitting units for emitting blue light.

The packaging film layer 4 covers the light-emitting device layer 2 to prevent water vapor from entering the interior of the light-emitting device layer 2. The light-emitting device layer 2 is located in the display area AA, a portion of the packaging film layer 4 is located in the display area AA and covers the light-emitting device layer 2, and the other portion is located in the non-display area NA to reduce the risk of infiltration of water, oxygen, and the like from the non-display area NA of the display panel into the display area AA. The packaging film layer 4 may include a plurality of different film layers. The number and type of the film layers in the packaging film layer 4 are not limited by the embodiments of the present application.

The dam 7 is disposed in the non-display area NA and on the same layer as the light-emitting device layer 2. The dam 7 can limit part of the film layer in the packaging film layer 4 to a side, facing the display area AA, of the dam 7. The first blocking portion 3 is disposed on a side, away from the substrate, of the dam 7, that is, the first blocking portion 3 is also located in the non-display area NA. The dam 7 may be formed by stacking various film layers. For example, the dam 7 may be formed by stacking an inorganic layer and a metal layer.

Since the dam 7 is located on a side of the display area in the first direction X, the first obstruction portion 3 is also located on a side of the display area AA in the first direction X. For example, the first direction X is perpendicular to a thickness direction Y of the display panel. The first blocking portion 3 includes the first portion 31 and the second portion 32, where the second portion 32 is located on the side, away from the substrate 1, of the first portion 31, that is, in the thickness direction Y, the second portion 32 and the substrate 1 are respectively located on two sides of the first portion 31.

The second portion 32 extends at least partially beyond the first portion 31 in the first direction X, that is, an orthographic projection of the second portion 32 on the substrate 1 is at least partially outside that of the first portion 31 on the substrate 1. The second portion 32 may exceed beyond the first portion 31 on a side near the display area AA, or exceed beyond the first portion 31 on a side away from the display area AA, which is not limited by the embodiments of the present application.

It should be noted that the orthographic projection of the second portion 32 on the substrate 1 may fully cover and exceed beyond the first portion 31, or the orthographic projection of the second portion 32 on the substrate 1 only overlaps with part of the structure in the first portion 31, which is not limited by the embodiments of the present application. Further, a size of the second portion 32 in the first direction X may be greater than that of the first portion 31 in the first direction X, or may be equal to or less than that of the first portion 31 in the first direction X.

At least one film layer of the packaging film layer 4 extends to a side, away from the light-emitting device layer 2, of the first blocking portion 3 via the outer contours of the dam 7, the first portion 31, and the second portion 32. Specifically, at least one film layer in the packaging film layer 4 is located in the display area AA and covers the light-emitting device layer 2, and the film layer extends from the display area AA to the non-display area NA and reaches the dam 7, then extends along the dam 7 to the position of the first portion 31 in the first blocking portion 3, extends along the outer contour of the first portion 31 in a direction away from the substrate 1 and reaches the second portion 32, and continues to extend along the outer contour of the second portion 32. Since the second portion 32 extends at least partially beyond the first portion 31 in the first direction X, the film layer extends in a curved manner at the position where the second portion 32 exceeds beyond the first portion 31. Therefore, the extension length of the film layer at the second portion 32 increases. Finally, the film layer reaches a side, away from the light-emitting device layer 2, of the first portion 31, continues to extend along the outer contours of the first portion 31 and the dam 7, and ultimately leaves the first blocking portion 3 and the dam 7.

In the embodiments of the present application, the first blocking portion 3 is added to the dam 7, so that the extension length of at least one film layer in the packaging film layer 4 increases. In addition, since the second portion 32 in the first blocking portion 3 extends at least partially beyond the first portion 31 in the first direction X, the film layer needs to extend in a curved manner at the corresponding position of the second portion 32, which can further increase the extension length. Further, if cracks occur in part of the film layer of the packaging film layer 4, this design will increase the path that the cracks extend to the display area AA, which can reduce the risk of extension of the cracks to the display area AA, thereby improving the reliability of the packaging film layer 4 and meeting the packaging requirements of the display panel.

It should be noted that the number of the dam 7 may be plural, and the plurality of dams 7 are disposed side by side. On this basis, the display panel may include not only the first blocking portion 3, but also a second blocking portion 5 or even more blocking portions having the same structure as the first blocking portion 3, as shown in FIG. 4. Meanwhile, the first blocking portion 3 may be located on a side, near the display area, of the second blocking portion 5, or on a side, away from the display area, of the second blocking portion 5, which is not limited by the embodiments of the present application.

In some embodiments, with reference to FIGS. 2, 3, and 5, the second portion 32 includes a first protrusion 321, and an orthographic projection of the first protrusion 321 on the substrate 1 is located outside that of the first portion 31 on the substrate 1. The packaging film layer 4 includes a first inorganic layer 41, the first inorganic layer 41 includes a first sub segment 411 and a second sub segment 412 connected to each other, the first sub segment 411 is located on a side, facing the substrate 1, of the second portion 32, and an orthographic projection of the first sub segment 411 on the substrate 1 is located within the orthographic projection of the first protrusion 321 on the substrate 1. A thickness of at least a portion of the first sub segment 411 is less than a thickness of the second sub segment 412.

The packaging film layer 4 includes the first inorganic layer 41, a portion of the first inorganic layer 41 is located in the display area AA and covers the light-emitting device layer 2, and the other portion is located in the non-display area NA. At the position of the first blocking portion 3, the first inorganic layer 41 extends along the outer contours of the first portion 31 and the second portion 32, and extends from a side, near the display area AA, of the first blocking portion 3 to a side, away from the display area AA, of the first blocking portion 3.

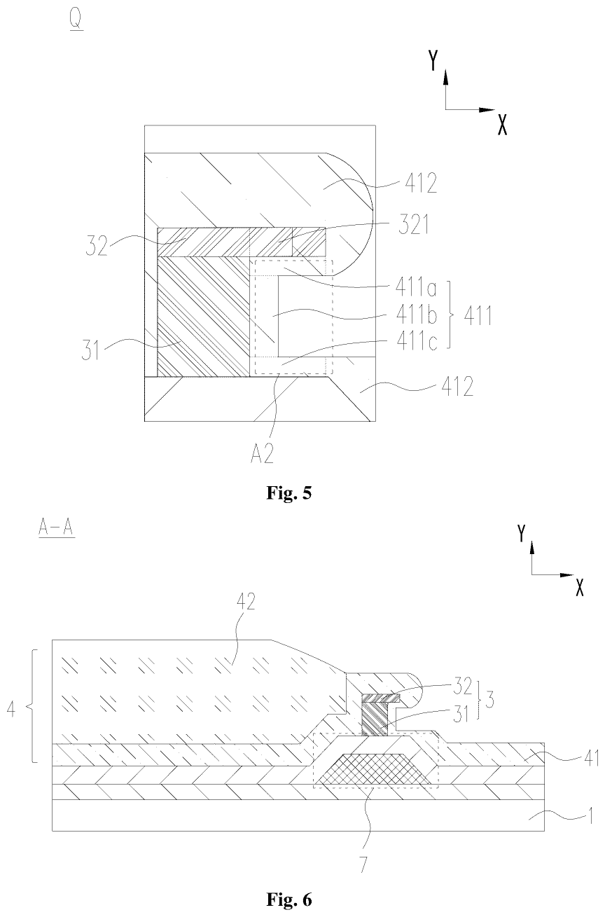

The first protrusion 321 is a structure in the second portion 32 that extends beyond the first portion 31, the orthographic projection of the first protrusion 321 on the substrate 1 is located on a side of the orthographic projection of the first portion 31 on the substrate 1 in the first direction X, and the first protrusion 321 may be located on a side, near the display area AA, of the first portion 31 or on a side, away from the display area AA, of the first portion 31. Since the first protrusion 321 protrudes from the first portion 31 in the first direction X, the first protrusion 321 and the first portion 31 may jointly form a second accommodating space A2, where the first sub segment 411 in the first inorganic layer 41 is located in the second accommodating space A2. In FIG. 5, the second accommodating space A2 is represented by a dashed frame.

The second sub segment 412 is connected to the first sub segment 411, the second sub segment 412 includes two portions, one portion is located on a side, away from the substrate 1, of the second portion 32, and an orthographic projection of the other portion on the substrate 1 is misaligned and adjacent to that of the second portion 32 on the substrate 1.

The first inorganic layer 41 is usually fabricated by chemical vapor deposition or the like. In the manufacturing process of the first inorganic layer 41, due to the obstruction of the first protrusion 321, the deposition of materials located in the second accommodating space A2 is reduced, so that the thickness of at least a portion of the first sub segment 411 formed in the second accommodating space A2 is less than the thickness of the second sub segment 412. Even the materials located in the second accommodating space A2 are difficult to mold continuously, so that the first sub segment 411 has a plurality of portions independent of each other.

Further, because at least a portion of the first sub segment 411 is thinner and even may fracture, the difficulty of extension of cracks at the first sub segment 411 increases. Therefore, when cracks occur in the first inorganic layer 41, the presence of the first sub segment 411 can further reduce the difficulty of extension of the cracks into the display area AA, thereby improving the packaging reliability of the packaging film layer 4.

In some embodiments, the first sub segment 411 includes a first segment 411a attached to the first protrusion 321, a second segment 411b attached to the first portion 31 and connected to the first segment 411a, and a third segment 411c connected to the second segment 411b and opposite to the first segment 411a in the thickness direction Y, and the thickness of at least one of the first segment 411a, the second segment 411b, and the third segment 411c is less than that of the second sub segment 412.

The first segment 411a and the third segment 411c are both connected to the second sub segment 412, the second segment 411b connects the first segment 411a and the third segment 411c together, the second segment 411b is located on a side of the first portion 31 in the first direction X and attached to the first portion 31, the second segment 411b has a first end and a second end in the thickness direction Y, the first end is located on a side, away from the substrate 1, of the second end, the first segment 411a is connected to the first end, and the third segment 411c is connected to the second end.

In a manufacturing process, a reaction gas diffuses into the second accommodating space A2, adsorbs on surfaces of structures such as the first protrusion and the first portion 31, and undergoes chemical reactions to form the first segment 411a, the second segment 411b, and the third segment 411c. In this process, due to the obstruction of the first protrusion, it is difficult for the reaction gas to enter the second accommodating space A2, so that the thickness of at least one of the first segment 411a, the second segment 411b, and the third segment 411c is less than that of the second sub segment 412. Optionally, the thicknesses of the first segment 411a, the second segment 411b, and the third segment 411c are all less than that of the second sub segment 412.

In some embodiments, with reference to FIG. 1 and FIG. 6, the packaging film layer 4 further includes a first organic layer 42 disposed on a side, away from the substrate 1, of the first inorganic layer 41, and the first organic layer 42 is located on a side, facing the display area AA, of the first blocking portion 3.

The inorganic material has a strong capability of blocking water and oxygen, but its low elasticity makes it prone to fracture. Although the organic material has a poor capability of blocking water and oxygen, the presence of the organic material can reduce the risk of fracture of the inorganic material. Therefore, the first organic layer 42 is added on the basis of the first inorganic layer 41 in the embodiments of the present application, thereby improving the packaging effect and reliability of the packaging film layer 4.

The first organic layer 42 can cover the light-emitting device layer 2, and the first organic layer 42 is located on the side, facing the display area AA, of the first blocking portion 3 in the first direction X. Similar to the dam 7, the first blocking portion 3 can limit the first organic layer 42. Therefore, the first blocking portion 3 can increase the blocking height of the display panel at the corresponding position of the dam 7, thereby further reducing the risk of crossing of the first organic layer 42 over the dam 7 and reducing the manufacturing difficulty of the packaging film layer 4.

It should be noted that the risk of occurrence of cracks in the packaging film layer 4 within the display area AA is relatively low in the presence of the first organic layer 42. However, on the side, away from the display area AA, of the first blocking portion 3, the first organic layer 42 does not exist in the packaging film layer 4, so cracks are prone to occur in the first inorganic layer 41 there under an external force, while the presence of the first blocking portion 3 reduces the risk of inward extension of the cracks there towards the display area AA, thereby improving the reliability of the packaging film layer 4.

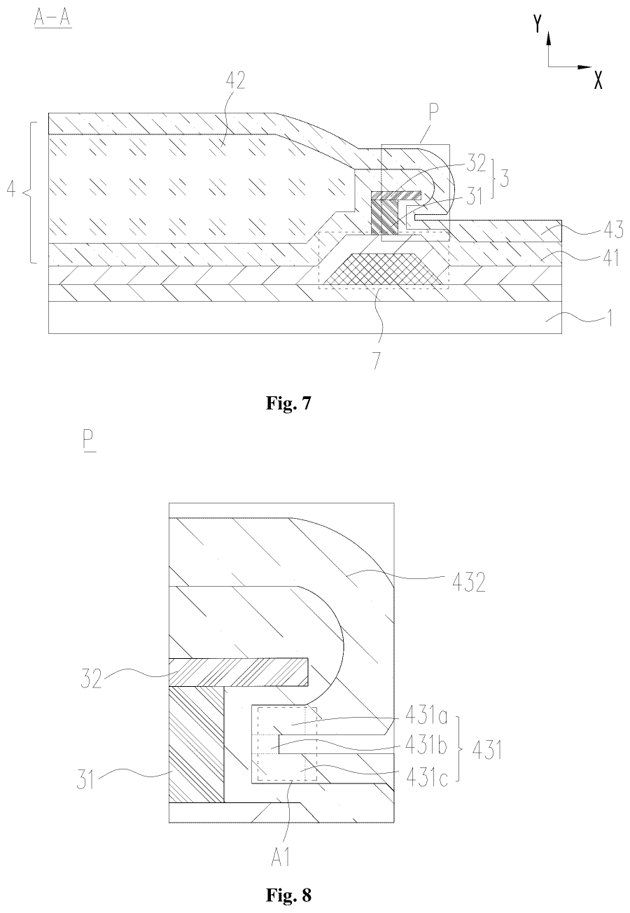

In some embodiments, with reference to FIG. 7 and FIG. 8, the packaging film layer 4 further includes a second inorganic layer 43 located on a side, away from the substrate 1, of the first organic layer 42, the first sub segment 411 encloses a first accommodating space A1, the second inorganic layer 43 includes a third sub segment 431 and a fourth sub segment 432 connected to each other, and the third sub segment 431 is located in the first accommodating space A1.

On the side, near the display area AA, of the first blocking portion 3, the first inorganic layer 41 and the second inorganic layer 43 are respectively located on two sides of the first organic layer 42 in the thickness direction Y. The first inorganic layer 41 and the second inorganic layer 43 can fully cover the first organic layer 42, thereby reducing the flow of the first organic layer 42. Meanwhile, the solution of overlapping the organic and inorganic layers can improve the packaging effect of the packaging film layer 4. On the side, away from the display area AA, of the first blocking portion 3, since there is no the first organic layer 42, the first inorganic layer 41 is attached to the second inorganic layer 43.

With reference to FIG. 5, in the manufacturing process, the second inorganic layer 43 is formed after the first inorganic layer 41. After the first inorganic layer 41 is fabricated, the first segment 411a, the second segment 411b, and the third segment 411c located in the second accommodating space A2 jointly enclose the first accommodating space A1. The third sub segment 431 in the second inorganic layer 43 is formed in the first accommodating space A1. For example, the third sub segment 431 includes a fourth segment 431a attached to the first segment 411a, a fifth segment 431b attached to the second segment 411b, and a sixth segment 431c attached to the third segment 411c.

In some embodiments, the thickness of at least a portion of the third sub segment 431 is less than that of the fourth sub segment 432.

Similar to the first sub segment 411, it is also difficult for the reaction gas to enter the first accommodating space A1, so that the amount of material deposition in the first accommodating space A1 decreases, and then the thickness of at least a portion of the third sub segment 431 formed in the first accommodating space A1 is less than that of the fourth sub segment 432.

In the embodiments of the present application, since the second portion 32 extends at least partially beyond the first portion 31 in the first direction X, the extension lengths of the first inorganic layer 41 and the second inorganic layer 43 increase. Further, the first inorganic layer 41 is enabled to form the first sub segment 411 with a small thickness, and the second inorganic layer 43 is enabled to form the third sub segment 431 with a small thickness. Cracks are difficult to extend at the first sub segment 411 and the third sub segment 431, thereby reducing the risk of occurrence of cracks in the first inorganic layer 41 and the second inorganic layer 43 within the display area AA and improving the packaging reliability of the packaging film layer 4.

In some embodiments, the first protrusion 321 is located on the side, away from the display area AA, of the first portion 31.

It can be seen from the above content that the presence of the first protrusion 321 enables the first inorganic layer 41 and the second inorganic layer 43 to form the first sub segment 411 and the third sub segment 431 with small thicknesses, where the first sub segment 411 and the third sub segment 431 can increase the difficulty of inward extension of cracks, thereby reducing the risk of extension of the cracks into the display area AA.

Further, in the embodiments of the present application, the first protrusion 321 is disposed on the side, away from the display area AA, of the first portion 31, so that the first sub segment 411 and the third sub segment 431 are formed on the side, away from the display area AA, of the first portion 31, thereby blocking cracks on the side, away from the display area AA, of the first portion 31 and further reducing the risk of extension of the cracks to the display area AA.

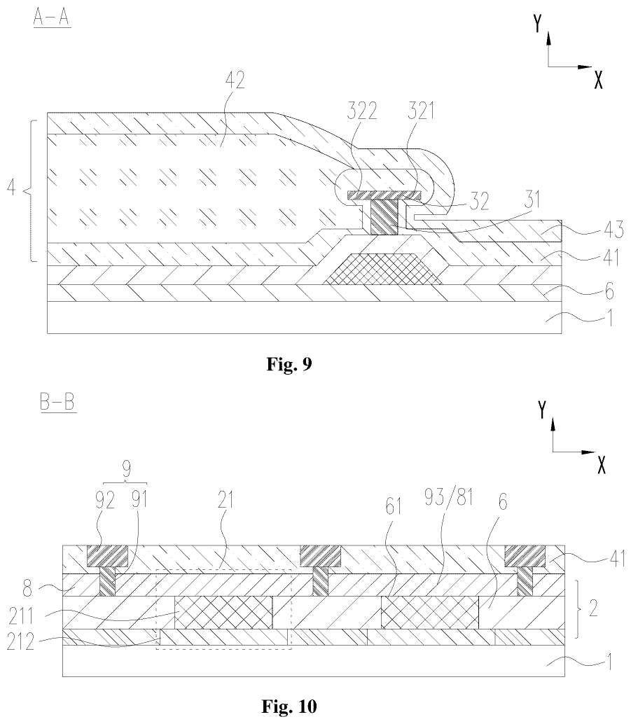

In some embodiments, with reference to FIG. 1 and FIG. 9, the second portion 32 further includes a second protrusion 322, and the second protrusion 322 is located on the side, near the display area AA, of the first portion 31.

The first protrusion 321 and the second protrusion 322 are respectively located on two sides of the first portion 31 in the first direction X, that is, a size of the second portion 32 in the first direction X is greater than that of the first portion 31 in the first direction X. The design of the second protrusion 322 can further increase the extension lengths of the first inorganic layer 41 and the second inorganic layer 43, and partial thicknesses of the first inorganic layer 41 and the second inorganic layer 43 decrease at the corresponding position of the second protrusion 322 and on a side, near the substrate 1, of the second protrusion 322, thereby further blocking the cracks and improving the reliability of the packaging film layer 4. Optionally, the first protrusion 321 and the second protrusion 322 are axially symmetrically distributed.

In some embodiments, with reference to FIGS. 1, 3, and 9, the display panel further includes a pixel definition layer 6, the pixel definition layer 6 includes a plurality of first openings 61, a plurality of light-emitting layers 211 of the light-emitting device layer 2 are accommodated in the first openings 61 respectively, and the pixel definition layer 6 includes an inorganic material.

The dam 7 includes a third portion 71, and the third portion 71 is disposed on the same layer with the same material as the pixel definition layer 6 and attached to the first inorganic layer 41.

In related technologies, the inorganic layer in the packaging film layer 4 mainly laps with a metal, and also laps with an organic film layer. However, due to differences in materials, the adhesion between the inorganic layer and the metal or organic film layer in the packaging film layer 4 is poor, making the film layer prone to separate under the impact of an external force.

In the embodiments of the present application, the first opening 61 in the pixel definition layer 6 are used for defining the light-emitting layer 211 in the light-emitting device layer 2. The light-emitting layer 211 is a portion of the light-emitting unit 21. For example, the light-emitting unit 21 further includes a first electrode located on a side, away from the substrate 1, of the light-emitting layer 211, and a second electrode 212 located on a side, facing the substrate 1, of the light-emitting layer 211.

The pixel definition layer 6 includes an inorganic material, and the third portion 71 in the dam 7 is disposed on the same layer with the same material as the pixel definition layer 6. Therefore, the third portion 71 can be fabricated in the same process as the pixel definition layer 6 to reduce process complexity, and the third portion 71 also includes the inorganic material.

The third portion 71 and the first inorganic layer 41 are both made of inorganic materials and bonded. This design can improve the adhesion effect between the dam 7 and the first inorganic layer 41, reduce the risk of separation between the two, and improve the reliability of internal structures of the display panel. Optionally, the pixel definition layer 6 includes at least one of silicon nitride and silicon oxide. Further, the first inorganic layer 41 may also include at least one of silicon nitride and silicon oxide.

In some embodiments, with reference to FIG. 9 and FIG. 10, the display panel further includes a defining portion 9 located in the display area AA and disposed on a side, away from the substrate 1, of the pixel definition layer 6, the defining portion 9 includes a first sub portion 91 and a second sub portion 92 located on a side, away from the substrate 1, of the first sub portion 91, the first sub portion 91 is disposed on the same layer with the same material as the first portion 31, and the second sub portion 92 is disposed on the same layer with the same material as the second portion 32.

The defining portion 9 is located on the side, away from the substrate 1, of the pixel definition layer 6, where the defining portion 9 can increase the height of the display panel at the position of the pixel definition layer 6. When the packaging film layer 4 packages the light-emitting unit 21, the presence of the defining portion 9 can separate at least part of the structure in the packaging film layer 4 into independent packaging portions, which can prevent water vapor and the like from spreading among the independent packaging portions and further improve the packaging effect.

In addition, the first sub portion 91 and the first portion 31 are disposed on the same layer with the same material, so that the first sub portion 91 and the first portion 31 may be fabricated in the same process; and the second sub portion 92 and the second portion 32 are disposed on the same layer with the same material, so that the second sub portion 92 and the second portion 32 may be fabricated in the same process, which can simplify the manufacturing process of the display panel and improve the manufacturing efficiency.

In some embodiments, the second sub portion 92 extends at least partially beyond the first sub portion 91 in the first direction X. The structure of the defining portion 9 is similar to that of the first blocking portion 3. In the manufacturing process of the packaging film layer 4, at least one film layer in the packaging film layer 4 can be separated by the defining portion 9 to form a plurality of packaging structures corresponding to the light-emitting units 21, thereby achieving independent packaging of each light-emitting unit 21 and further improving the packaging effect.

In addition, the presence of the defining portion 9 can further reduce the risk of lateral leakage in adjacent light-emitting units. Specifically, in the manufacturing process of the display panel, the pixel definition layer 6 is usually formed first, then defining portions 9 are formed on the pixel definition layer 6, and film layers such as a light-emitting layer 211, a hole transport layer (not shown in the figures), and an electron transport layer (not shown in the figures) are formed between the adjacent defining portions 9. Since the second sub portion 92 of the defining portion 9 extends at least partially beyond the first sub portion 91 in the first direction X, the second sub portion 92 is partially suspended relative to the first sub portion 91, making it difficult for the light-emitting layer 211, the hole transport layer, and the electron transport layer to climb a slope at the suspended position, and resulting in fracture. That is, the presence of the defining portion 9 can separate the film layers such as the light-emitting layer 211, the hole transport layer, and the electron transport layer into separate structures, so as to reduce the risk of lateral leakage in the film layers.

In some embodiments, the light-emitting device layer 2 further includes a first electrode layer 8 disposed on the side, away from the substrate 1, of the light-emitting layer 211, the first electrode layer 8 includes a plurality of first electrodes 81, the defining portion 9 forms a plurality of second openings 93, the material of the first sub portion 91 and/or the second sub portion 92 includes a metal material, and two adjacent first electrodes 81 are connected to each other through the defining portion 9.

The metal material usually has conductivity, so the adjacent first electrodes 81 can transmit signals through the defining portion 9. In the embodiments of the present application, the plurality of first electrodes 81 are separated from each other through the defining portion 9 and connected to each other through the defining portion 9, that is, the plurality of first electrodes 81 and the defining portion 9 jointly form a common electrode for driving the light-emitting layers 211 to emit light.

In some embodiments, the material of the first sub portion 91 includes a metal material, and the material of the second sub portion 92 includes an inorganic material.

The first sub portion 91 includes the metal material, so the adjacent first electrodes 81 can achieve conduction through the first sub portion 91. On this basis, in the embodiments of the present application, the material of the second sub portion 92 includes an inorganic material, so that the second sub portion 92 can adhere reliably to some inorganic film layers in the packaging film layer 4, thereby improving packaging reliability.

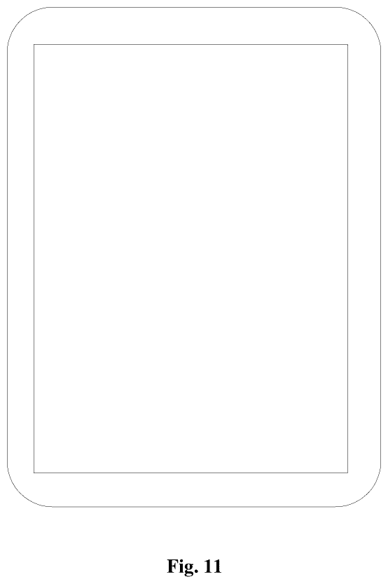

In a second aspect, with reference to FIG. 11, an embodiment of the present application provides a display device, including the display panel in any of the foregoing embodiments.

It should be noted that the display device provided in the embodiment of the present application has the beneficial effects of the display panel in any of the foregoing embodiments. Refer to the foregoing description of the display panel for details. The details will not be repeated in the embodiment of the present application.

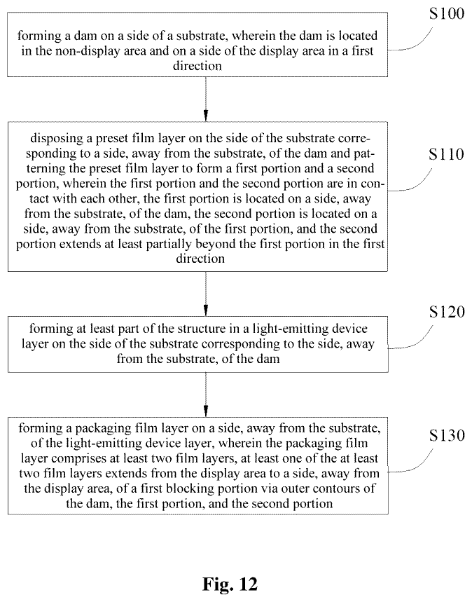

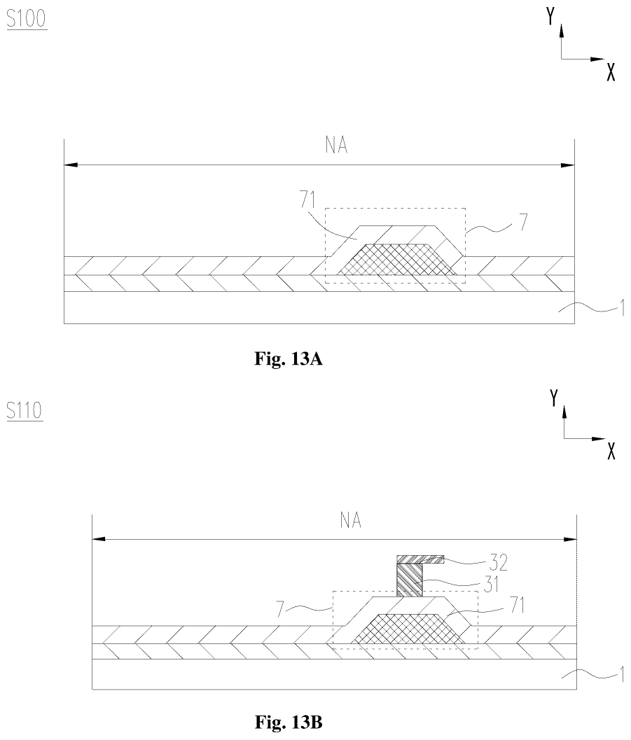

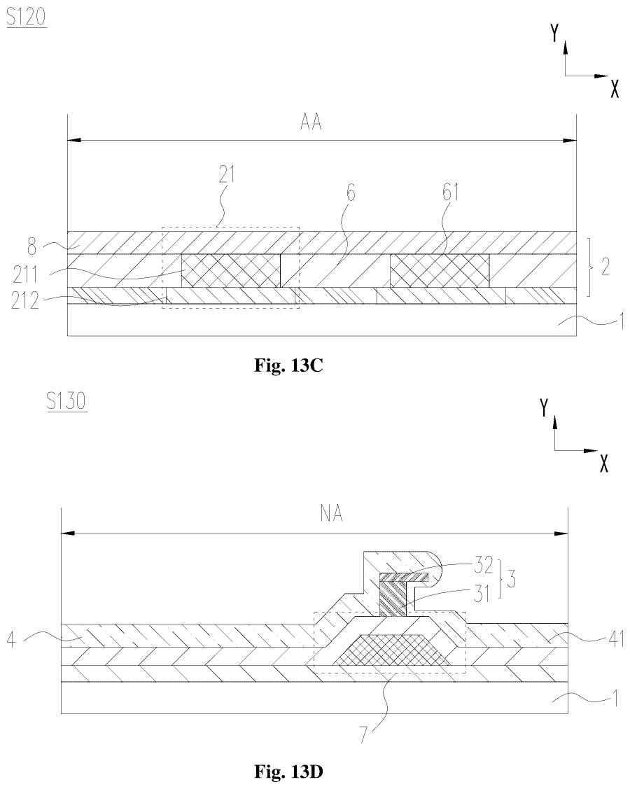

In a third aspect, with reference to FIG. 12 and FIG. 13, an embodiment of the present application provides a method of manufacturing a display panel, the display panel has a display area AA and a non-display area NA located on a periphery of the display area AA, and the method includes:
S100: Form a dam on a side of a substrate, where the dam is located in the non-display area and on a side of the display area in a first direction, and the first direction is parallel to a plane where the substrate is located.

In step S100, with reference to FIG. 13A, the dam 7 is disposed in the non-display area NA. The dam 7 can isolate part of a film layer in a packaging film layer on a side, near the display area AA, of the dam 7 when the packaging film layer is subsequently fabricated.
S110: Dispose a preset film layer on the same side of the substrate and pattern the preset film layer to form a first portion and a second portion in contact with each other, where the first portion is located on a side, away from the substrate, of the dam, the second portion is located on the side, away from the substrate, of the dam, and the second portion extends at least partially beyond the first portion in the first direction.

In step S110, with reference to FIG. 13B, the preset film layer (not shown in the figure) is formed on the same side of the substrate 1 as the dam 7, and the preset film layer is used for forming the first portion 31 and the second portion 32. Specifically, the preset film layer includes two portions that are laminated, and materials of the two portions may be the same or different. Since the second portion 32 to be formed by the preset film layer needs to exceed beyond the first portion 31 in the first direction X, compared to the first portion 31, the preset film layer needs to be preferentially patterned to form the second portion 32 by etching or the like. Then, the preset film layer is patterned to form the first portion 31 by etching or the like.

It should be noted that the second portion 32 may exceed beyond the first portion 31 on a side near the display area, or exceed beyond the first portion 31 on a side away from the display area, which is not limited by the embodiments of the present application.
S120: Form at least part of the structure in a light-emitting device layer on the same side of the substrate.

In step S120, with reference to FIG. 13C, the light-emitting device layer 2 is formed in the display area AA, where the light-emitting device layer 2 includes a plurality of light-emitting units 21, and the plurality of light-emitting units 21 include but are not limited to red light-emitting units, blue light-emitting units, and green light-emitting units.

It should be noted that the light-emitting device layer 2 includes multiple layers of structures, where part of the film layer structure may be formed after step S110, and part of the film layer structure may alternatively be formed before step S110, which is not limited by the embodiments of the present application. S130: Form a packaging film layer on a side, away from the substrate, of the light-emitting device layer, where at least one film layer of the packaging film layer extends to a side, away from the display area, of a first blocking portion via outer contours of the dam, the first portion, and the second portion.

In step S130, with reference to FIG. 13D, at least one film layer of the packaging film layer 4 is attached to the dam 7, the first portion 31, and the second portion 32 and extend to the side, away from the display area, of the first blocking portion 3. In this process, since the second portion 32 extends at least partially beyond the first portion 31 in the first direction X, the corresponding extension length of part of the film layer in the packaging film layer 4 increase. Further, if cracks occur in part of the film layer of the packaging film layer 4, this design will increase the path that the cracks extend to the display area, which can reduce the risk of extension of the cracks to the display area, thereby improving the reliability of the packaging film layer 4 and meeting the packaging requirements of the display panel.

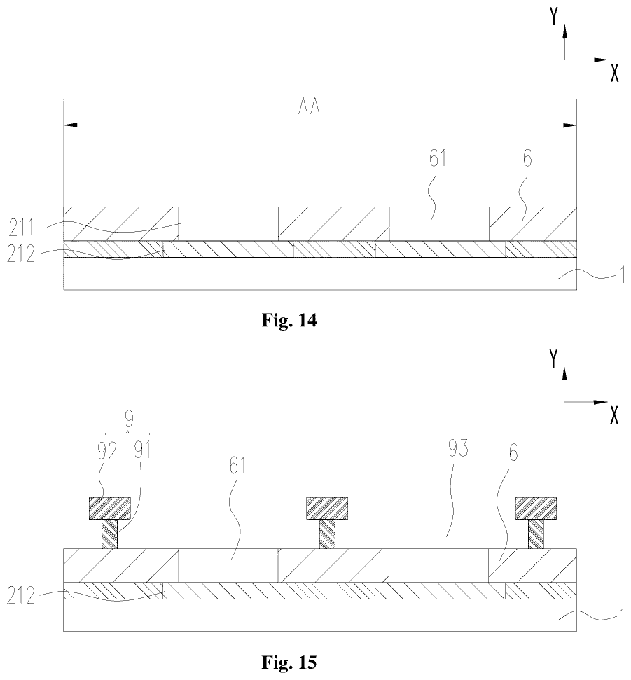

In some embodiments, with reference to FIG. 13A and FIG. 14, the dam 7 includes a third portion 71, and step S100 includes: forming a pixel definition material layer on a side of the substrate 1, and patterning the pixel definition material layer to form a pixel definition layer 6 and the third portion 71, where the pixel definition layer 6 includes a plurality of first openings 61 located in the display area AA.

The pixel definition material layer (not shown in the figures) may also form the third portion 71 of the dam 7 in addition to the pixel definition layer 6, which can reduce the manufacturing process. The pixel definition layer 6 is located in the display area AA, and the first openings 61 in the pixel definition layer 6 are used for defining light-emitting layers 211 in the light-emitting device layer 2. Further, alternatively, the material of the pixel definition material layer includes an inorganic material, that is, the third portion 71 includes an inorganic material. This design facilitates better adhesion between inorganic layers in the packaging film layer and the dam 7, thereby improving the reliability of the packaging film layer 4.

With reference to FIG. 15, step S110 includes: patterning the preset film layer to form a first sub portion 91 and a second sub portion 92 in contact with each other, where the first sub portion 91 is located on a side, away from the substrate 1, of the pixel definition layer 6, the second sub portion 92 is located on a side, away from the substrate 1, of the first sub portion 91, and the first sub portion 91 and the second sub portion 92 jointly form a plurality of second openings 93.

The first sub portion 91 and the second sub portion 92 are both located in the display area AA, and define the plurality of second openings 93 for manufacturing the light-emitting device layer. The second sub portion 92 is located on the side, away from the substrate 1, of the first sub portion 91, and optionally, the second sub portion 92 extends at least partially beyond the first sub portion 91 in the first direction X.

The first sub portion 91 and the first portion 31 are disposed on the same layer with the same material, and the first sub portion 91 and the first portion 31 can be fabricated in the same process; and the second sub portion 92 and the second portion 32 are disposed on the same layer with the same material, and the second sub portion 92 and the second portion 32 can be fabricated in the same process, which can simplify the manufacturing process of the display panel and improve the manufacturing efficiency.

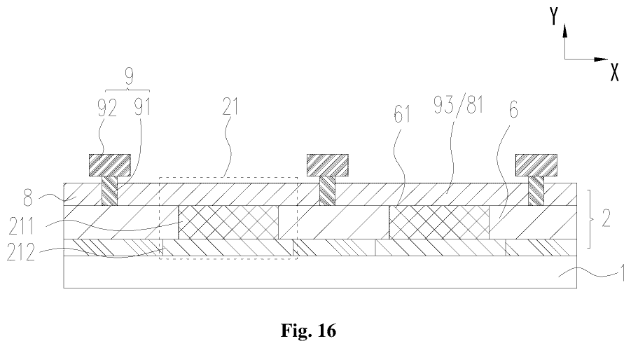

With reference to FIG. 16, the light-emitting device layer 2 includes a plurality of first electrodes 81, and step S120 includes: forming the first electrodes 81 in the second openings 93 respectively.

The plurality of first electrodes 81 may be formed in the plurality of second openings 93 respectively, and the first sub portion 91 and the second sub portion 92 may separate the plurality of first electrodes 81 independently. Optionally, at least one of the first sub portion 91 and the second sub portion 92 includes a metal material, that is, at least one of the first sub portion 91 and the second sub portion 92 can transmit electrical signals. On this basis, the first sub portion 91 and the second sub portion 92 can achieve mutual conduction between the plurality of first electrodes 81, that is, at least one of the first sub portion 91 and the second sub portion 92 can cooperate with the plurality of first electrodes 81 to form a common electrode.

It should be noted that, after the first sub portion 91 and the second sub portion 92 are formed and before the first electrodes 81 are formed, a plurality of functional film layers, such as a hole transport layer, a light-emitting layer 211, and an electron transport layer in the light-emitting unit 21 may be sequentially formed in the first openings 61 and the second openings 93.

Although the disclosed embodiments of the present application are as described above, the described content is only for the purpose of easy understanding of the present application and is not intended to limit the present invention. Any person skilled in the art of the present application may make any modifications and changes in forms and details of implementation without departing from the spirit and scope disclosed in the present application, but the scope of protection of the present application shall still be subject to the scope defined in the appended claims.

What is claimed is:

1. A display panel having a display area and a non-display area located on a periphery of the display area, the display panel comprising:
a substrate;
a light-emitting device layer disposed on a side of the substrate and located in the display area;
a dam disposed on the same side of the substrate as the light-emitting device layer and located in the non-display area, wherein the dam is located on a side of the display area in a first direction, and the first direction is parallel to a plane where the substrate is located;
a first blocking portion disposed on a side, away from the substrate, of the dam, wherein the first blocking portion comprises a first portion and a second portion, the second portion is located on a side, away from the substrate, of the first portion, and the second portion extends at least partially beyond the first portion in the first direction; and
a packaging film layer located on a side, away from the substrate, of the light-emitting device layer, wherein the packaging film layer comprises at least two film layers, at least one of the at least two film layers extends from the display area to a side, away from the display area, of the first blocking portion via outer contours of the dam, the first portion, and the second portion.

2. The display panel according to claim 1, wherein the second portion comprises a first protrusion, and an orthographic projection of the first protrusion on the substrate is located outside an orthographic projection of the first portion on the substrate;
the packaging film layer comprises a first inorganic layer, the first inorganic layer comprises a first sub segment and a second sub segment, the first sub segment and the second sub segment are connected to each other, the first sub segment is located on a side, facing the substrate, of the second portion, and an orthographic projection of the first sub segment on the substrate is located within the orthographic projection of the first protrusion on the substrate; and
a thickness of at least a portion of the first sub segment is less than a thickness of the second sub segment.

3. The display panel according to claim 2, wherein the first sub segment comprises a first segment attached to the first protrusion, a second segment attached to the first portion and connected to the first segment, and a third segment connected to the second segment and opposite to the first segment in a thickness direction of the substrate, and a thickness of at least one of the first segment, the second segment, and the third segment is less than a thickness of the second sub segment.

4. The display panel according to claim 3, wherein the thicknesses of the first segment, the second segment, and the third segment are all less than the thickness of the second sub segment.

5. The display panel according to claim 2, wherein the packaging film layer further comprises a first organic layer disposed on a side, away from the substrate, of the first inorganic layer, and the first organic layer is located on a side, facing the display area, of the first blocking portion.

6. The display panel according to claim 5, wherein the packaging film layer further comprises a second inorganic layer located on a side, away from the substrate, of the first organic layer; and
the first sub segment encloses a first accommodating space, the first accommodating space is located on a side, away from the substrate, of the blocking portion, the second inorganic layer comprises a third sub segment and a fourth sub segment connected to each other, and the third sub segment is located in the first accommodating space.

7. The display panel according to claim 6, wherein a thickness of at least a portion of the third sub segment is less than a thickness of the fourth sub segment.

8. The display panel according to claim 2, wherein the first protrusion is located on a side, away from the display area, of the first portion.

9. The display panel according to claim 8, wherein the second portion further comprises a second protrusion, and the second protrusion is located on a side, near the display area, of the first portion.

10. The display panel according to claim 9, wherein the first protrusion and the second protrusion are axially symmetrically distributed.

11. The display panel according to claim 2, further comprising a pixel definition layer, wherein the pixel definition layer comprises a plurality of first openings, a plurality of light-emitting layers of the light-emitting device layer are accommodated in the first openings respectively, and the pixel definition layer comprises an inorganic material; and
wherein the dam comprises a third portion, and the third portion is disposed on the same layer with the same material as the pixel definition layer and attached to the first inorganic layer.

12. The display panel according to claim 11, wherein the pixel definition layer comprises at least one of silicon nitride and silicon oxide.

13. The display panel according to claim 11, further comprising a defining portion, wherein the defining portion is located in the display area and disposed on a side, away from the substrate, of the pixel definition layer, the defining portion comprises a first sub portion and a second sub portion located on a side, away from the substrate, of the first sub portion, the first sub portion is disposed on the same layer with the same material as the first portion, and the second sub portion is disposed on the same layer with the same material as the second portion.

14. The display panel according to claim 13, wherein the second sub portion extends at least partially beyond the first sub portion in the first direction.

15. The display panel according to claim 13, wherein the light-emitting device layer further comprises a first electrode layer disposed on a side, away from the substrate, of the light-emitting layer, wherein the first electrode layer comprises a plurality of first electrodes; and
the defining portion forms a plurality of second openings, the material of the first sub portion or the material of the second sub portion comprises a metal material, and two adjacent first electrodes are connected to each other through the defining portion.

16. The display panel according to claim 13, wherein the light-emitting device layer further comprises a first electrode layer disposed on a side, away from the substrate, of the light-emitting layer, wherein the first electrode layer comprises a plurality of first electrodes; and
the defining portion forms a plurality of second openings, the material of the first sub portion and the material of the second sub portion comprises a metal material, and two adjacent first electrodes are connected to each other through the defining portion.

17. The display panel according to claim 13, wherein the material of the first sub portion comprises a metal material, and the material of the second sub portion comprises an inorganic material.

18. A display device, comprising the display panel according to claim 1.

19. A method of manufacturing the display panel according to claim 1, the display panel having a display area and a non-display area located on a periphery of the display area, the method comprising:
forming a dam on a side of a substrate, wherein the dam is located in the non-display area and on a side of the display area in a first direction, and the first direction is parallel to a plane where the substrate is located;
disposing a preset film layer on the side of the substrate corresponding to a side, away from the substrate, of the dam and patterning the preset film layer to form a first portion and a second portion, wherein the first portion and the second portion are in contact with each other, the first portion is located on a side, away from the substrate, of the dam, the second portion is located on a side, away from the substrate, of the first portion, and the second portion extends at least partially beyond the first portion in the first direction;
forming at least part of the structure in a light-emitting device layer on the side of the substrate corresponding to the side, away from the substrate, of the dam; and
forming a packaging film layer on a side, away from the substrate, of the light-emitting device layer, wherein the packaging film layer comprises at least two film layers, at least one of the at least two film layers extends from the display area to a side, away from the display area, of a first blocking portion via outer contours of the dam, the first portion, and the second portion.

20. The method according to claim 19, wherein the dam comprises a third portion, and the step of forming a dam on a side of a substrate comprises:
forming a pixel definition material layer on a side of the substrate, and patterning the pixel definition material layer to form a pixel definition layer and the third portion, wherein the pixel definition layer comprises a plurality of first openings located in the display area;
the step of disposing a preset film layer on the side of the substrate corresponding to the side, away from the substrate, of the dam and patterning the preset film layer comprises:
patterning the preset film layer to form a first sub portion and a second sub portion, wherein the first sub portion and the second sub portion are in contact with each other, the first sub portion is located on a side, away from the substrate, of the pixel definition layer, the second sub portion is located on a side, away from the substrate, of the first sub portion, and the first sub portion and the second sub portion jointly form a plurality of second openings; and
the light-emitting device layer comprises a plurality of first electrodes, and the step of forming at least part of a structure in a light-emitting device layer on the side of the substrate corresponding to the side, away from the substrate, of the dam comprises:
forming the first electrodes in the second openings respectively.
